(19) United States
(12) Patent Application Publication
(10) Pub. No.: US 2017/0097279 A1
(43) Pub. Date: Apr. 6, 2017

(54) STRUCTURE MONITORING SYSTEM AND STRUCTURE MONITORING METHOD

(71) Applicant: Seiko Epson Corporation, Tokyo (JP)

(72) Inventor: Yoshiyuki MAKI, Suwa (JP)

(21) Appl. No.: 15/283,671

(22) Filed: Oct. 3, 2016

(30) Foreign Application Priority Data
Oct. 5, 2015 (JP) 2015-197948

(51) Int. Cl. G01M 5/00; G01R 33/032

(52) U.S. Cl. CPC G01M 5/0091; G01R 33/032; G01M 5/0066

(57) ABSTRACT

A structure monitoring system includes a magnetic sensor that detects an intensity of a magnetic field from a structure including a metal portion using characteristics of an energy transition of alkali metal atoms, and a control unit that determines a degree of soundness (a degree of fatigue of the metal portion) of the structure using a result of the detection of the magnetic sensor.

### CROSS REFERENCE

This application claims the benefit of Japanese Application No. 2015-197948, filed on Oct. 5, 2015. The disclosure of the prior application is hereby incorporated by reference herein in its entirety.

### BACKGROUND

1. Technical Field

The present invention relates to a structure monitoring system and a structure monitoring method.

2. Related Art

A structure monitoring system that monitors a degree of soundness of a structure including a metal portion such as rebars or steel frames is known (see, for example, Non-Patent Document 1 (Kouichi Sato, et al., “Basic Study for development of structure monitoring system”, Taisei Technology Center Report, Taisei Corporation, 2010, No. 43)).

For example, in a system described in Non-Patent Document 1, an acceleration sensor is installed in a structure, and a state (soundness) of the structure is confirmed using a detection result of the acceleration sensor.

In the system described in Non-Patent Document 1, abnormality of vibration of the structure caused by deterioration of rebars included in the structure can be recognized. However, there is a problem in that causes of the abnormality of the vibration (for example, whether or not the abnormality is abnormality of the vibration due to the deterioration of the rebars) cannot be specified.

### SUMMARY

An advantage of some aspects of the invention is to provide a structure monitoring system and a structure monitoring method capable of monitoring a degree of soundness (state) of a structure including a metal portion more accurately.

The advantage can be achieved by the following configurations.

A structure monitoring system according to an aspect of the invention includes a magnetic sensor that detects an intensity of a magnetic field from a structure including a metal portion using characteristics of an energy transition of alkali metal atoms; and a determination unit that determines a degree of soundness of the structure using a result of the detection of the magnetic sensor.

According to such a structure monitoring system, it is possible to determine a fatigue state of the metal portion of the structure using the magnetic sensor that detects the magnetic field from the structure including the metal portion (more specifically, the magnetic field caused with metal fatigue from the metal portion) using the characteristics of an energy transition of the alkali metal atoms. Therefore, it is possible to include information on the fatigue state of the metal portion in the result of determination as to the degree of soundness of the structure and, as a result, more accurately monitor the degree of soundness (state) of the structure including the metal portion.

It is preferable that the structure monitoring system according to the aspect of the invention further includes a vibration sensor that detects vibration of the structure, and the determination unit determines the degree of soundness using a result of the detection of the vibration sensor, in addition to the result of the detection of the magnetic sensor.

With this configuration, it is possible to include information on whether or not there is abnormality in vibration the entire structure, in a result of a determination as to the degree of soundness of the structure.

It is preferable that the structure monitoring system according to the aspect of the invention further includes a storage unit that stores vibration data regarding natural vibration of the structure, and the determination unit compares the detection result of the vibration sensor with the vibration data and determines the degree of soundness using a result of the comparison.

With this configuration, it is possible to simply and accurately determine whether or not there is abnormality in vibration of the entire structure and include a result of the determination, in a result of a determination as to the degree of soundness of the structure.

In the structure monitoring system according to the aspect of the invention, it is preferable that the determination unit determines a degree of fatigue of the metal portion using the detection result of the magnetic sensor.

With this configuration, it is possible to include information on a fatigue state of the metal portion in the result of the determination as to the degree of soundness of the structure.

In the structure monitoring system according to the aspect of the invention, it is preferable that the magnetic sensor includes: an atom cell filled with alkali metal; a light source unit that irradiates the atom cell with light; and a light detection unit that detects the light transmitted through the atom cell, and a body portion including the atom cell, the light source unit, and the light reception unit and formed as a unit is attached to the structure.

With this configuration, it is possible to realize the magnetic sensor using a nonlinear magneto-optical effect or an electromagnetically induced transparency phenomenon. Further, the atom cell can be installed near the metal portion and, as a result, the magnetic field from the metal portion can be detected with high accuracy.

In the structure monitoring system according to the aspect of the invention, it is preferable that the magnetic sensor includes a circuit unit which is electrically connected to the light source unit and the light detection unit, and the circuit unit is separated from the body portion.

With this configuration, a unit including the atom cell is on the internal side of the structure with respect to the circuit unit, and the unit can be easily installed near the metal portion.

In the structure monitoring system according to the aspect of the invention, it is preferable that, when the atom cell and the metal portion are viewed from an alignment direction, the atom cell is included in the metal portion.

With this configuration, it is possible to cause the magnetic field from the metal portion to suitably act on the atom cell. Therefore, it is possible to detect the magnetic field from the metal portion with high accuracy using the magnetic sensor.

It is preferable that the structure monitoring system according to the aspect of the invention further includes a communication unit that wirelessly transmits the detection result of the magnetic sensor.

With this configuration, in a case in which there are a plurality of magnetic sensors, it is possible to easily collect detection results of the magnetic sensors.

It is preferable that in the structure monitoring system according to the aspect of the invention, the communication unit is driven by power from a battery.

With this configuration, it is possible to detect the magnetic field from the structure using the magnetic sensor and perform monitoring of the degree of soundness of the structure using a result of the detection in an environment in which there is no commercial power supply.

In the structure monitoring system according to the aspect of the invention, it is preferable that the magnetic sensor detects an intensity of a magnetic field using a non-linear magneto-optical effect of the alkali metal atoms.

With this configuration, it is possible to detect the magnetic field from the metal portion with high accuracy using the magnetic sensor.

In the structure monitoring system according to the aspect of the invention, it is preferable that the magnetic sensor detects an intensity of a magnetic field using an electromagnetically induced transparency phenomenon of the alkali metal atoms.

With this configuration, it is possible to detect the magnetic field from the metal portion with high accuracy using the magnetic sensor.

A structure monitoring method according to an aspect of the invention includes: preparing a magnetic sensor that detects an intensity of a magnetic field using characteristics of an energy transition of alkali metal atoms; attaching the magnetic sensor to a structure including a metal portion; detecting a change in the magnetic field caused by fatigue of the metal portion using the magnetic sensor; and determining a degree of soundness of the structure using a result of the detection of the magnetic sensor.

According to such a structure monitoring method, it is possible to determine a fatigue state of the metal portion of the structure using the magnetic sensor that detects the magnetic field from the structure including the metal portion (more specifically, the magnetic field caused with metal fatigue from the metal portion) using the characteristics of an energy transition of the alkali metal atoms. Therefore, it is possible to include information on the fatigue state of the metal portion in the result of determination as to the degree of soundness of the structure and, as a result, more accurately monitor the degree of soundness (state) of the structure including the metal portion.

### BRIEF DESCRIPTION OF THE DRAWINGS

The invention will be described with reference to the accompanying drawings, wherein like numbers reference like elements.

FIG. 1 is a diagram illustrating an example of a use state of a structure monitoring system according to a first embodiment of the invention.

FIG. 2 is a block diagram illustrating a schematic configuration of the structure monitoring system illustrated in FIG. 1.

FIG. 3 is a diagram illustrating an installation state of a magnetic sensor included in the structure monitoring system illustrated in FIG. 1.

FIG. 4 is a cross-sectional view of a sensor body portion included in the magnetic sensor illustrated in FIG. 3.

FIG. 5 is a block diagram illustrating a control system of the magnetic sensor illustrated in FIG. 3.

FIG. 6 is a graph illustrating a relationship between a magnetic flux density of cesium atoms and an energy transition state.

FIG. 7 is a graph illustrating a relationship between a distortion of a metal portion included in the structure and an intensity of a magnetic field generated with the distortion.

FIG. 8 is a graph illustrating a relationship between a magnetic field detected by a magnetic sensor and the amount of vibration detected by a vibration sensor.

FIG. 9 is a flowchart illustrating a method of using the structure monitoring system illustrated in FIG. 1 (structure monitoring method).

FIG. 10 is a diagram illustrating a schematic configuration of a magnetic sensor used in a structure monitoring system according to a second embodiment of the invention.

### DESCRIPTION OF EXEMPLARY EMBODIMENTS

Preferred embodiments of a structure monitoring system and a structure monitoring method according to the invention will be described with reference to the accompanying drawings.

### First Embodiment

First, a first embodiment of the invention will be described.

Structure Monitoring System

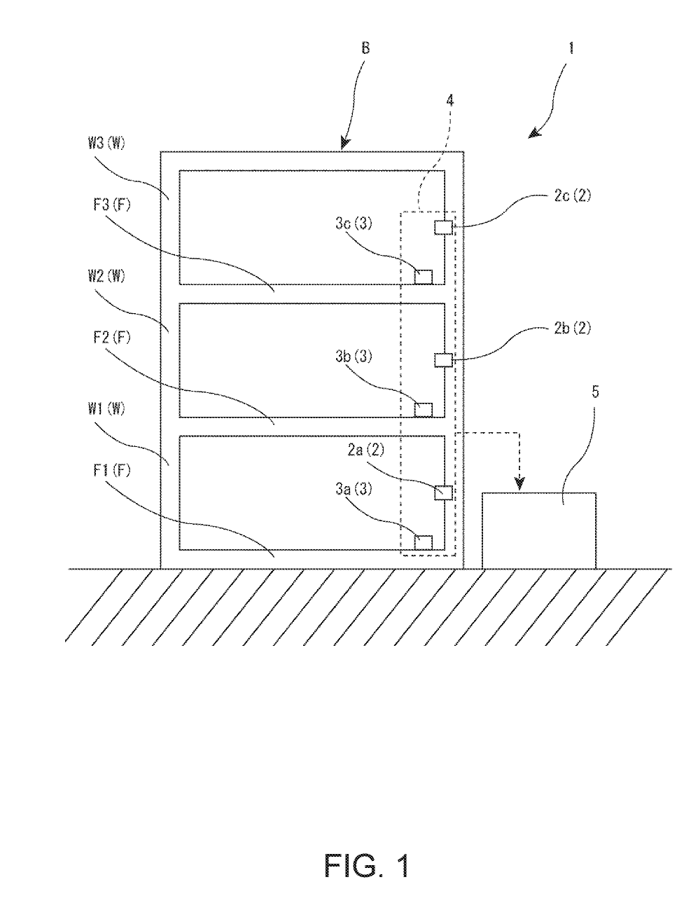

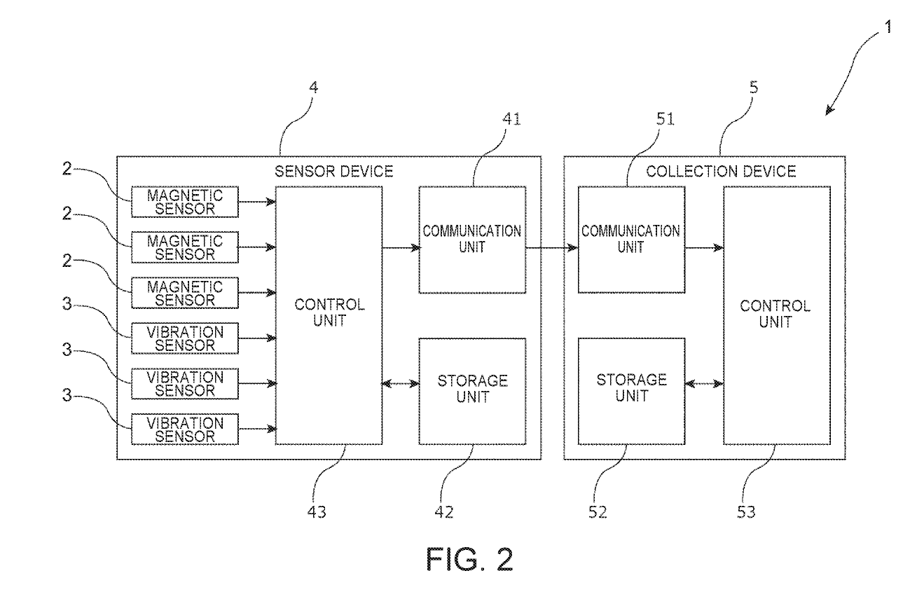

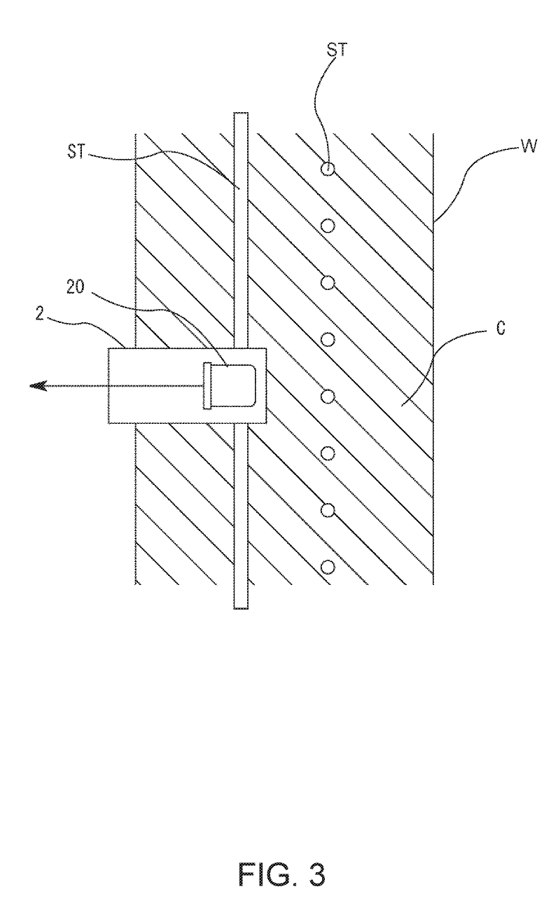

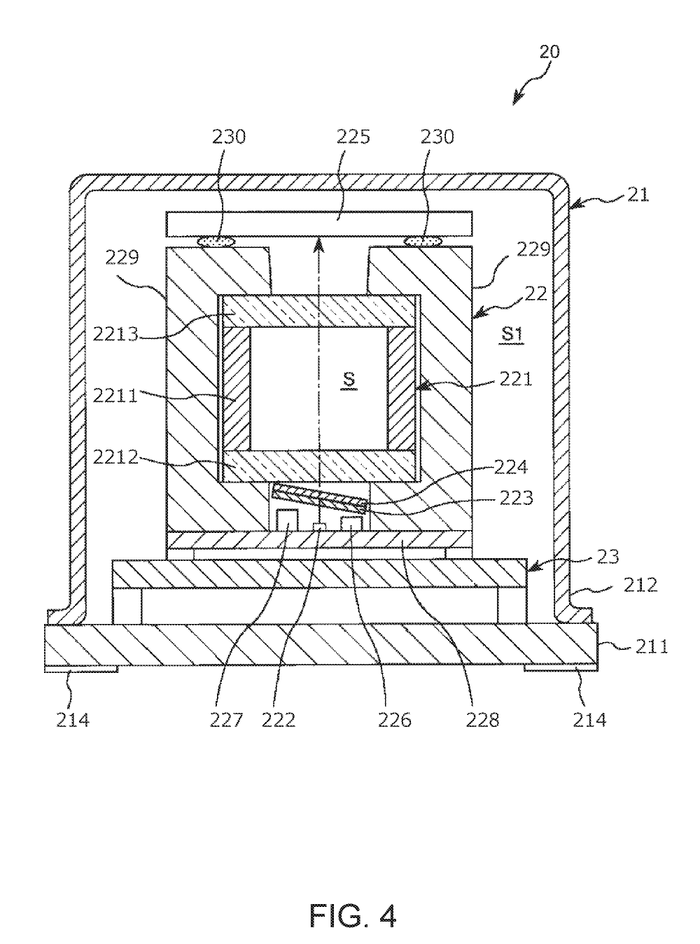

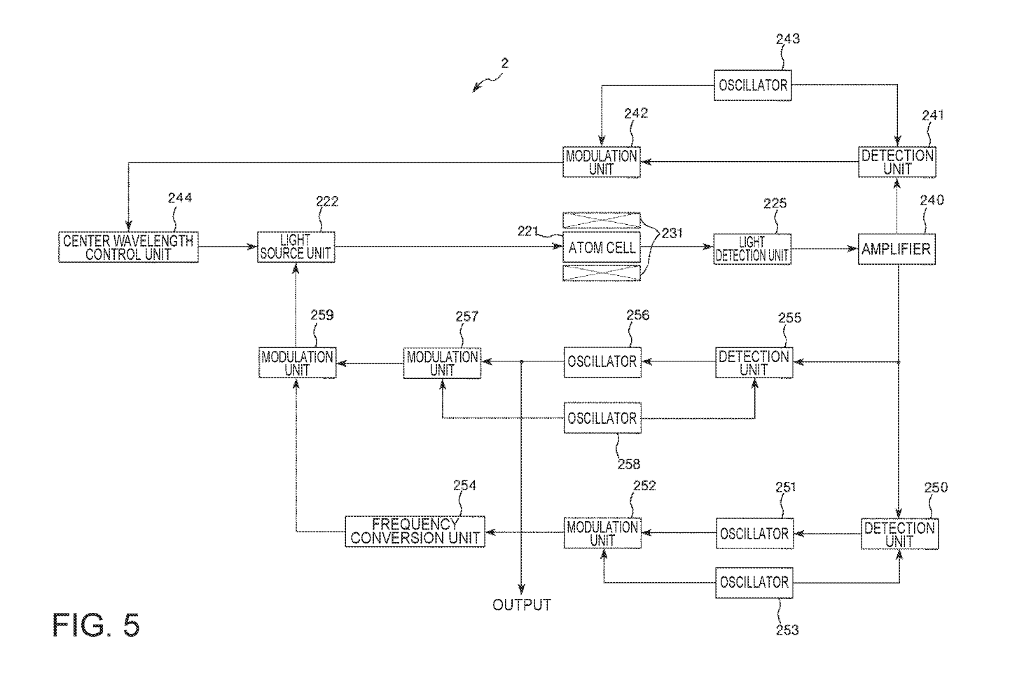

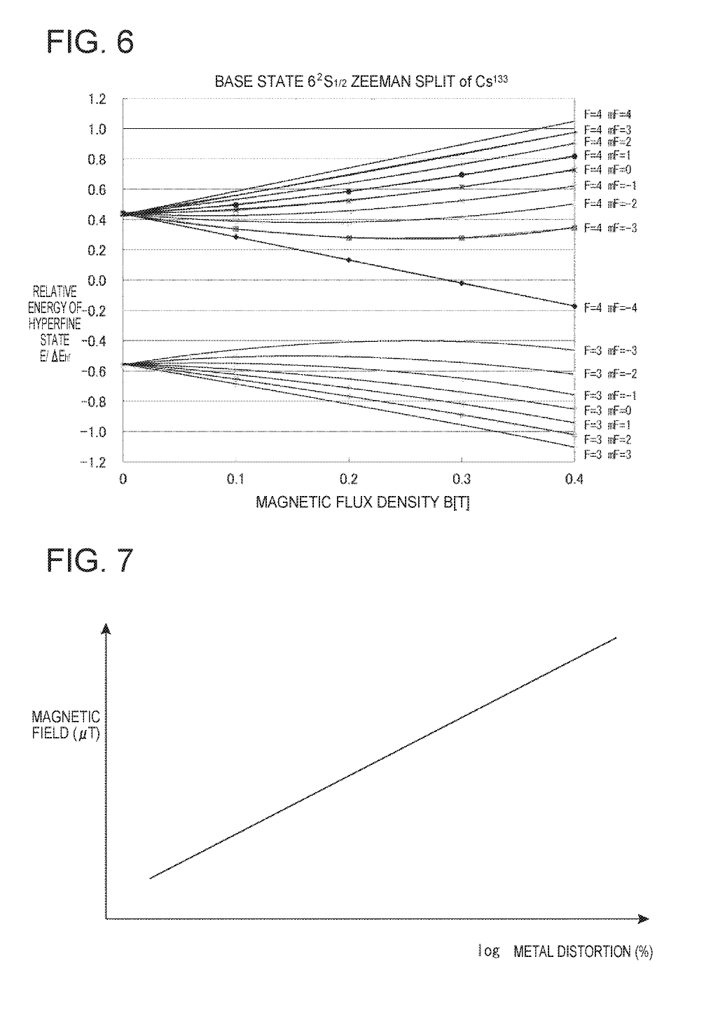

FIG. 1 is a diagram illustrating an example of a use state of a structure monitoring system according to a first embodiment of the invention. FIG. 2 is a block diagram illustrating a schematic configuration of the structure monitoring system illustrated in FIG. 1. FIG. 3 is a diagram illustrating an installation state of a magnetic sensor included in the structure monitoring system illustrated in FIG. 1. FIG. 4 is a cross-sectional view of a sensor body portion included in the magnetic sensor illustrated in FIG. 3. FIG. 5 is a block diagram illustrating a control system of the magnetic sensor illustrated in FIG. 3. FIG. 6 is a graph illustrating a relationship between a magnetic flux density and an energy transition state of cesium atoms.

The structure monitoring system 1 (hereinafter simply referred to as a “system 1”) illustrated in FIG. 1 monitors a degree of soundness (state) of a structure B. This system 1 includes a sensor device 4 that measures a state of the structure B, and a collection device 5 (logger) that collects a measurement result of the sensor device 4.

Here, for convenience of description, the structure B is a building structure having a three-story rebar concrete structure or rebar steel concrete structure. Further, the sensor device 4 includes a plurality of magnetic sensors 2 (2a, 2b, and 2c) installed on walls W (W1, W2, and W3) of respective stories of the structure B, and a plurality of vibration sensors 3 (3a, 3b, and 3c) installed on floors F (F1, F2, and F3) of the respective stories of the structure B. In the sensor device 4, each magnetic sensor 2 detects a magnetic field from a metal portion of the structure B, and each vibration sensor 3 detects vibration of the structure B, and the sensors send detection results to the collection device 5.

The collection device 5 collects the detection result transmitted from the sensor device 4, and determines the degree of soundness of the structure B using the collected detection result. A result of this determination is, for example, displayed on a display device (not illustrated) or is input to a personal computer, a portable terminal, or the like.

Hereinafter, the sensor device 4 and the collection device 5 will be sequentially described in detail.

### Sensor Device

As illustrated in FIG. 2, the sensor unit 4 includes a plurality of magnetic sensors 2, a plurality of vibration sensors 3, a communication unit 41 that transmits detection results of the sensors, a storage unit 42, and a control unit 43.

### Magnetic Sensor

The magnetic sensor 2 has a function of detecting intensity of the magnetic field from the structure B using a characteristic of an energy transition of alkali metal atoms. This magnetic sensor 2 is installed on the wall W, as illustrated in FIG. 3. Here, the wall W includes a metal portion ST such as reinforcing steel, and a concrete portion C that reinforces the metal portion ST, and at least a portion (body portion 20) of the magnetic sensor 2 is embedded into the concrete portion C of the wall W.

The body portion 20 of the magnetic sensor 2 includes an atom cell unit 22 that generates a quantum interference effect as described above, a package 21 that accommodates the atom cell unit 22, and a support member 23 that is accommodated in the package 21 and supports the atom cell unit 22 against the package 21, as illustrated in FIG. 4. Although not illustrated, a coil (a coil 231 illustrated in FIG. 5) is disposed to surround the atom cell unit 22 inside the package 21 or outside the package 21.

Further, the atom cell unit 22 includes an atom cell 221, a light source unit 222, optical components 223 and 224, a light detection unit 225, a heater 226, a temperature sensor 227, a substrate 228, and a holding member 229, which are formed as units. Specifically, the light source unit 222, the heater 226, the temperature sensor 227, and the holding member 229 are mounted on an upper surface of the substrate 228, the atom cell 221 and the optical components 223 and 224 are held by the holding member 229, and the light detection unit 225 is bonded to the holding member 229 through an adhesive 230.

Hereinafter, the respective units of the body portion 20 of the magnetic sensor 2 will be described.

The atom cell 221 is filled with alkali metal such as gaseous rubidium, cesium, or sodium. Further, the atom cell 221 may be filled with a noble gas such as argon or neon, or an inert gas such as nitrogen, as a buffer gas, together with the alkali metal gas, if necessary.

As illustrated in FIG. 4, the atom cell 221 includes a body portion 2211 having a columnar through-hole, and a pair of light transmissive portions 2212 and 2213 that block both openings of the through-hole. Accordingly, an internal space S filled with the alkali metal as described above is formed.

Here, each of the light transmissive portions 2212 and 2213 of the atom cell 221 has transmissivity to light (resonant light pair) from the light source unit 222. A material of the light transmissive portions 2212 and 2213 is not particularly limited as long as the material has transmissivity to the excitation light as described above, and may include, for example, a glass material or a quartz.

Further, the material of the body portion 2211 of the atom cell 221 is not particularly limited, and may be a silicon material, a ceramic material, a metal material, a resin material, or the like or may be a glass material, a crystal, or the like, similar to the light transmissive portions 2212 and 2213.

Each of the light transmissive portions 2212 and 2213 is hermetically bonded to the body portion 2211. Accordingly, an internal space S of the atom cell 221 can be an airtight space. A method of bonding the body portion 2211 and the light transmissive portions 2212 and 2213 of the atom cell 221 is determined according to a constituent material and is not particularly limited. For example, a bonding method using an adhesive, a direct bonding method, and an anodic bonding method may be used.

The light source unit 222 emits a resonant light pair (resonant light 1 and resonant light 2) that includes two types of lights having different frequencies that resonate with the alkali metal atoms in the atom cell 221 described above. The light source unit 222 is not particularly limited as long as light source unit can emit the light as described above. For example, a semiconductor laser such as a vertical cavity surface emitting laser (VCSEL) may be used.

The alkali metal has an energy level of a three-level system, and can take three states including two base states (base states 1 and 2) with different energy levels, and an excitation state. Here, base state 1 is an energy state lower than base state 2. When the alkali metal is irradiated with two types of resonant lights 1 and 2 emitted from the light source unit 222, a light absorption rate (light transmittance) in the alkali metal of resonant lights 1 and 2 changes according to a difference (ω1−ω2) between a frequency ω1 of resonant light 1 and a frequency ω2 of resonant light 2.

When the difference (ω1−ω2) between the frequency W1 of resonant light 1 and the frequency ω2 of resonant light 2 matches a frequency corresponding to an energy difference between base state 1 and base state 2, excitation from base states 1 and 2 to the excitation state stops. In this case, resonant lights 1 and 2 are both transmitted without being absorbed into the alkali metal. Such a phenomenon is referred to as a CPT phenomenon or an electromagnetically induced transparency (EIT) phenomenon.

For example, if the frequency ω1 of resonant light 1 is fixed and the frequency ω2 of resonant light 2 is changed, a detection intensity of the light detection unit 225 steeply increases with the above-described EIT phenomenon when the difference (ω1−ω2) between the frequency ω1 of resonant light 1 and the frequency ω2 of resonant light 2 matches a frequency ω0 corresponding to an energy difference between base state 1 and base state 2. Such a steep signal is detected as an EIT signal. This EIT signal has a unique value determined by a type of alkali metal.

As illustrated in FIG. 4, a plurality of optical components 223 and 224 are provided on an optical path for light between the light source unit 222 and the atom cell 221 as described above. In this embodiment, the optical component 223 and the optical component 224 are disposed in this order from the light source unit 222 to the atom cell 221.

The optical component 223 is a λ/4 wavelength plate. Accordingly, the light (excitation light) from the light source unit 222 can be converted from linearly polarized light to a circularly polarized light (right circularly polarized light or left circularly polarized light). In a state in which the alkali metal atoms in the atom cell 221 are Zeeman-split by the magnetic field of the coil 231 illustrated in FIG. 5, if the alkali metal atoms are irradiated with excitation light of circular polarization, the number of the alkali metal atoms at a desired energy level among a plurality of levels in which the alkali metal atoms are Zeeman-split by an interaction between the excitation light and the alkali metal atoms can be increased relative to the number of alkali metal atoms at another energy level. Therefore, the number of atoms expressing a desired EIT phenomenon increases, and the intensity of a desired EIT signal increases.

The coil 231 may be a solenoid coil or may be a Helmholtz coil. Further, the magnetic field generated by the coil 231 may have constant magnitude (or amplitude) and may be any one of a DC magnetic field, an AC magnetic field or may be a magnetic field in which the DC magnetic field and the AC magnetic field overlap.

The optical component 224 is a neutral density filter (ND filter). Accordingly, the intensity of the light incident on the atom cell 221 can be adjusted (reduced).

Other optical components such as a lens and a polarization plate may be disposed, in addition to the wavelength plate and the neutral density filter, between the light source unit 222 and the atom cell 221. Further, the optical component 224 may be omitted according to the intensity of the light from the light source unit 222.

The light detection unit 225 has a function of detecting an intensity of the excitation light (resonant light 1 and 2) transmitted through the inside of the atom cell 221. The light detection unit 225 is not particularly limited so long as the light detection unit can detect the excitation light as described above. For example, a photodetector (light reception element) such as a solar cell or a photodiode may be used.

The heater 226 includes a heating resistor (heating unit) that generates heat due to energization. The heat from the heater 226 is transferred to the atom cell 221 through the substrate 228 and the holding member 229.

The temperature sensor 227 detects temperature of the heater 226 or the atom cell 221. On the basis of a result of the detection of the temperature sensor 227, the heating amount of the heater 226 described above is controlled. Accordingly, it is possible to maintain the alkali metal atoms in the atom cell 221 at a desired temperature.

In this embodiment, the temperature sensor 227 is provided on the substrate 228. An installation position of the temperature sensor 227 is not limited thereto. For example, the temperature sensor 227 may be installed on the holding member 229, may be installed on the heater 226, or may be installed on an outer surface of the atom cell 221.

Each temperature sensor 227 is not particularly limited. Various known temperature sensors such as a thermistor and a thermocouple may be used.

The holding member 229 thermally connects the heater 226 to the respective light transmissive portions 2212 and 2213 of the atom cell 221. Accordingly, heat from the heater 226 can be transferred to the respective light transmissive portions 2212 and 2213 by thermal conduction of the holding member 229, and the light transmissive portions 2212 and 2213 can be heated.

It is preferable for a material having excellent heat conductivity such as a metal material to be used as a constituent material of the holding member 229. Further, it is preferable for a non-magnetic material to be used as the constituent material of the holding member 229 not to interfere with a magnetic field from the outside to the atom cell 221 or a magnetic field from the coil 231, similar to the package 21 to be described below.

The substrate 228 has a function of supporting the light source unit 222, the heater 226, the temperature sensor 227, and the holding member 229 described above. Further, the substrate 228 has a function of transferring heat from the heater 226 to the holding member 229. Accordingly, even when the heater 226 is separated from the holding member 229, the heat from the heater 226 can be transferred to the holding member 229.

Here, the substrate 228 thermally connects the heater 226 to the holding member 229. By mounting the heater 226 and the holding member 229 on the substrate 228 in this way, it is possible to increase a degree of freedom of installation of the heater 226.

Further, since the light source unit 222 is mounted on the substrate 228, temperature of the light source unit 222 on the substrate 228 can be adjusted by the heat from the heater 226.

Further, the substrate 228 includes wirings (not illustrated) electrically connected to the light source unit 222, the heater 226, and the temperature sensor 227.

A constituent material of the substrate 228 is not particularly limited. For example, the constituent material may include a ceramic material or a metallic material. One of these may be used alone or two or more types of materials may be combined and used. For example, an insulating layer formed of a resin material, a metal oxide, or a metal nitride may be provided on a surface of the substrate 228 for the purpose of prevention of short-circuit of wirings included in the substrate 228, as necessary. Further, it is preferable for a non-magnetic material to be used as the constituent material of the substrate 228 not to interfere with a magnetic field from the outside to the atom cell 221 or a magnetic field from the coil 231, similar to the package 21 to be described below.

The substrate 228 may be omitted according to a shape of the holding member 229, an installation position of the heater 226, or the like. In this case, the heater 226 may be installed at a position at which the heater 226 comes into contact with the holding member 229.

The package 21 has a function of accommodating the atom cell unit 22 and the support member 23, as illustrated in FIG. 4. Components other than the above-described components may be accommodated in the package 21.

The package 21 includes a plate-like base 211 (base portion), and a bottomed cylindrical lid 212 (lid portion), as illustrated in FIG. 4. An opening of the lid 212 is blocked by the base 211. Accordingly, an internal space S1 that accommodates the atom cell unit 22 and the support member 23 is formed.

The base 211 supports the atom cell unit 22 via the support member 23. Further, the base 211 is, for example, a wiring substrate. A plurality of terminals 214 are provided on a lower surface of the base 211. Although not illustrated, the plurality of terminals 214 are electrically connected to a plurality of terminals provided on an upper surface of the base 211 via a wire penetrating the base 211. The light source unit 222 and the substrate 228 described above are electrically connected to the base 211 via a wiring (not illustrated) (for example, a flexible wiring substrate or a bonding wire).

A constituent material of the base 211 is not particularly limited. For example, a resin material, a ceramic material, or the like may be used. However, it is preferable for the ceramic material to be used. Accordingly, it is possible to provide excellent airtightness of the internal space S1 while realizing the base 211 constituting the wiring substrate.

The lid 212 is bonded to the base 211. A method of bonding the base 211 and the lid 212 is not particularly limited. For example, brazing and soldering, seam welding, or energy beam welding (laser welding, electron beam welding, or the like) may be used. A bonding member for bonding the base 211 and the lid 212 may be interposed between the base 211 and the lid 212.

Further, it is preferable for the base 211 and the lid 212 to be hermetically bonded. That is, it is preferable for the inside of the package 21 to be an airtight space. Accordingly, the inside of the package 21 can be in a reduced pressure state and, as a result, it is possible to improve characteristics of the body portion 20. In particular, it is preferable for the inside of the package 21 to be in a reduced pressure state (vacuum). Accordingly, it is possible to further improve the characteristics of the body portion 20.

A constituent material of the lid 212 is not particularly limited as long as the material can form the airtight space as described above due to its magnetic transmissivity. For example, a resin material, a ceramic material, or a metal material may be used.

The support member 23 (support portion) is accommodated in the package 21, and has a function of supporting the atom cell unit 22 against the package 21 (more specifically, the base 211 constituting a portion of the package 21). Further, the support member 23 has a function of suppressing transfer of heat between the atom cell unit 22 and the outside of the package 21. Accordingly, it is possible to suppress thermal interference between the respective portions of the atom cell unit 22 and the outside.

This support member 23 is bonded to each of the base 211 and the substrate 228 of the package 21 by, for example, adhesive.

Further, a constituent material of the support member 23 is not particularly limited. For example, it is preferable for a non-metal such as a resin material or a ceramic material to be used, and it is more preferable for the resin material to be used. Further, it is preferable for a non-magnetic material to be used as the constituent material of the support member 23 not to interfere with a magnetic field from the outside to the atom cell 221 or a magnetic field from the coil 231.

The configuration of the body portion 20 of the magnetic sensor 2 has been described above.

As illustrated in FIG. 5, the magnetic sensor 2 includes a center wavelength control unit 244, an amplifier 240, a detection unit 241, a modulation unit 242, an oscillator 243, a detection unit 250, an oscillator 251, a modulation unit 252, an oscillator 253, a frequency conversion unit 254, a detection unit 255, an oscillator 256, a modulation unit 257, an oscillator 258, and a modulation unit 259, in addition to the body portion 20 described above. These constitute a “circuit unit” electrically connected to the light source unit 222 and the light detection unit 225.

In laser light emitted by the light source unit 222, a center wavelength λ0 is controlled on the basis of an output of the center wavelength control unit 244, and modulation is applied on the basis of an output of the modulation unit 259. For example, in a case in which a laser driver that supplies a driving current to the light source unit 222 is used as the center wavelength control unit 244, modulation is applied to the laser light emitted by the light source unit 222 by superimposing an alternating current output by the modulation unit 259 on the driving current. The output of the modulation unit 259 is feedback controlled so that the light corresponding to the modulated component becomes resonant light 1 or resonant light 2 with respect to the alkali metal atoms, as described below.

The output signal of the light detection unit 225 is amplified by the amplifier 240 and input to the detection unit 241, the detection unit 250, and the detection unit 255.

The detection unit 241 synchronously detects the output signal of the amplifier 240 using an oscillation signal of the oscillator 243. The modulation unit 242 modulates an output signal of the detection unit 241 using the oscillation signal of the oscillator 243. The oscillator 243 may oscillate, for example, at a low frequency on the order of tens of Hz to hundreds of Hz. The center wavelength control unit 244 controls a center wavelength λ0 of the laser light emitted by the light source unit 222 according to the output signal of the modulation unit 242. The center wavelength λ0 is stabilized by a feedback loop passing through the light source unit 222, the atom cell 221, the light detection unit 225, the amplifier 240, the detection unit 241, the modulation unit 242, and the center wavelength control unit 244.

The detection unit 250 synchronously detects the output signal of the amplifier 240 using the oscillation signal of the oscillator 253. The oscillator 251 is an oscillator of which the oscillation frequency changes according to the magnitude of the output signal of the detection unit 250. The oscillator 251 may be realized by, for example, a voltage controlled crystal oscillator (VCXO). The modulation unit 252 modulates the output signal of the oscillator 251 using the oscillation signal of the oscillator 253. The oscillator 253 may oscillate, for example, at a low frequency on the order of tens of Hz to hundreds of Hz.

The frequency conversion unit 254 converts the output signal of the modulation unit 252 into a signal at a frequency equal to ½ (in the case of cesium atoms, 9.1926 GHz/2=4.5963 GHz) of a frequency difference corresponding to an energy difference between two base levels of the alkali metal atoms having the magnetic quantum number m=0 filled in the atom cell 221. The frequency conversion unit 254 may be realized by, for example, a phase locked loop (PLL) circuit. The frequency conversion unit 254 may convert the output signal of the modulation unit 252 into a signal at a frequency equal to the frequency difference (in the case of cesium atoms, 9.1926 GHz) corresponding to an energy difference between two base levels of the alkali metal atoms having the magnetic quantum number m=0 filled in the atom cell 221.

The detection unit 255 synchronously detects the output signal of the amplifier 240 using the oscillation signal of the oscillator 258. The oscillator 256 is an oscillator of which the oscillation frequency changes according to the magnitude of the output signal of the detection unit 255. The oscillator 256 may be realized by, for example, a voltage controlled crystal oscillator (VCXO). Here, the oscillator 256 oscillates at a sufficiently low frequency Δω (for example, about 1 MHz to 10 MHz) with respect to a frequency corresponding to a width of Doppler broadening of an excitation level of the alkali metal atoms filled in the atom cell 221. The modulation unit 257 modulates the output signal of the oscillator 256 using the oscillation signal of the oscillator 258. The oscillator 258 may oscillate, for example, at a low frequency on the order of tens of Hz to hundreds of Hz.

The modulation unit 259 modulates the output signal of the frequency conversion unit 254 using the output signal of the modulation unit 257 (may modulate the output signal of the modulation unit 257 using the output signal of the frequency conversion unit 254). The modulation unit 259 may be realized by a frequency mixer, a frequency modulation (FM) circuit, an amplitude modulation (AM) circuit, or the like. As described above, the laser light emitted by light source unit 222 is modulated on the basis of the output of the modulation unit 259, and a plurality of resonant light 1 and resonant light 2 are generated.

In the magnetic sensor 2 having this configuration, if a magnetic field is applied to the atom cell 221, base level 1 (F=3) and base level 2 (F=4) of the alkali metal atoms are divided into a plurality of Zeeman split levels in which the magnetic quantum number m is different, as illustrated in FIG. 6. In both of base level 1 and base level 2, an energy difference Eδ between two Zeeman split levels in which the magnetic quantum numbers m are different by 1 is proportional to the intensity of the magnetic field. Further, feedback control is applied so that the signal intensity of the output signal of the light detection unit 225 (the output signal of the amplifier 240) is maximized. The signal intensity of the output signal of the light detection unit 225 (the output signal of the amplifier 240) is maximized when a relationship (Δω=2δ is preferable) of 2×δ×n=Δω or Δω×n=2×δ (n is a positive integer) with respect to the oscillation frequency Δω of the oscillator 256 and the frequency δ corresponding to the energy difference Eδ between the Zeeman split levels is satisfied. That is, since the oscillation frequency Δω of the oscillator 256 is proportional to the intensity of the magnetic field, the intensity of the magnetic field can be detected by using the oscillation signal of the oscillator 256 as the output signal. Here, the magnetic field is always generated by the coil 231, but an intensity of an external magnetism can be calculated by obtaining a relative frequency of the output signal on the basis of the oscillation frequency of the oscillator 256 when the intensity of the external magnetism is 0.

The magnetic sensor 2 detects the intensity of the magnetic field using an electromagnetically induced transparency phenomenon of the alkali metal atoms, as described above. Accordingly, the magnetic field from the metal portion ST can be detected with high accuracy using the magnetic sensor 2.

Further, since the body portion 20 that is a unit including the atom cell 221, the light source unit 222, and the light detection unit 225 is attached to the structure B, the atom cell 221 can be installed near the metal portion ST and, as a result, the magnetic field from the metal portion ST can be detected with high accuracy.

Here, when the atom cell 221 and the metal portion ST are viewed in an alignment direction, it is preferable for the atom cell 221 to be contained in the metal portion ST. Accordingly, the magnetic field from the metal portion ST can suitably act on the atom cell 221. Therefore, it is possible to detect the magnetic field from the metal portion ST with high accuracy using the magnetic sensor 2.

Further, it is preferable for a circuit unit electrically connected to the light source unit 222 and the light detection unit 225 to be separate from the body portion 20. Accordingly, the body portion 20 including the atom cell 221 is on an internal side of the structure B with respect to the circuit unit, such that the body portion 20 can be easily installed near the metal portion ST.

### Vibration Sensor

The vibration sensor 3 has a function of detecting the vibration of the structure B. The vibration sensor 3 is not particularly limited as long as the vibration sensor can detect the vibration. For example, the vibration sensor includes an acceleration sensor, an angular velocity sensor, or the like.

### Communication Unit

The communication unit 41 illustrated in FIG. 2 has a function of wirelessly transmitting measurement information including the detection results of the magnetic sensor 2 and the vibration sensor 3 described above (hereinafter simply referred to as “measurement information”). The wirelessly transmitted measurement information is received by the collection device 5. The communication unit 41 may transmit information obtained by processing the detection results of the magnetic sensor 2 and the vibration sensor 3 in the control unit 43, as the measurement information.

Although not illustrated, this communication unit 41 includes an antenna, and a communication circuit. The antenna is not particularly limited. However, the antenna is formed of, for example, a metal material or carbon, and has a form such as a winding or a thin film. The communication circuit includes, for example, a transmission circuit for transmitting electromagnetic waves, and a modulation circuit having a function of modulating a signal to be transmitted. Further, The communication circuit may include a down-converter circuit having a function of converting a frequency of a signal into a low frequency, an up-converter circuit having a function of converting a frequency of a signal into a high frequency, an amplification circuit having a function of amplifying a signal, and the like.

### Storage Unit

The storage unit 42 has a function of storing information such as the detection result of the magnetic sensor 2 and the detection result of the vibration sensor 3. The stored information is wirelessly transmitted by the above-described communication unit 41. Accordingly, the communication unit 41 can collectively wirelessly transmit the detection results of the magnetic sensor 2 and the vibration sensor 3 in a predetermined period of time.

This storage unit 42 is not particularly limited. Any one of a non-volatile memory and a volatile memory may be used. However, it is preferable for the non-volatile memory to be used from the viewpoint that an information storage state can be held without supply of power and power saving can achieved. In particular, it is preferable for a flash memory to be used from the viewpoint that information can be read and written with power saving.

### Control Unit

The control unit 43 has a function of controlling, for example, each unit constituting the sensor device 4 or processing information on the detection results of the magnetic sensor 2 and the vibrating sensor 3, as necessary. This control unit 43 includes, for example, an MPU. This control unit 43 may determine the degree of soundness of the structure B using the detection results of the magnetic sensor 2 and the vibration sensor 3, similar to the control unit 53 of the collection device 5 that will be described below. In this case, information on a result of the determination may be transmitted by the communication unit 41.

The configuration of the sensor device 4 has been described above. A power supply that drives the sensor device 4 configured in this way is not particularly limited. For example, a commercial power supply, or a secondary battery connected to a solar cell may be used.

According to the sensor device 4 as described above, by the communication unit 41 wirelessly transmitting the detection results of the plurality of magnetic sensors 2, it is possible to easily collect the detection results of magnetic sensors 2 using the collection device 5 even in a case in which there are a plurality of magnetic sensors 2.

Further, in a case in which the communication unit 41 is driven by power from a battery, it is possible to detect the magnetic field from the structure B using the magnetic sensor 2 and perform monitoring of the degree of soundness of the structure B using a result of the detection in an environment in which there is no commercial power supply.

### Collection Device

As illustrated in FIG. 2, the collection device 5 includes a communication unit 51 that receives information from the above-described sensor device 4 (information such as the detection result of the magnetic sensor 2 and the vibration sensor 3), a storage unit 52, and a control unit 53.

### Communication Unit

The communication unit 51 illustrated in FIG. 2 has a function of receiving measurement information wirelessly transmitted as described above. Although not illustrated, the communication unit 51 includes an antenna and a communication circuit, similar to the above-described communication unit 41. The communication circuit of the communication unit 51 includes, for example, a reception circuit for receiving electromagnetic waves, and a demodulation circuit having a function of demodulating a received signal. Further, the communication circuit of the communication unit 51 may include, for example, a down-converter circuit having a function of converting a frequency of a signal into a low frequency, an up-converter circuit having a function of converting the frequency of the signal into a high frequency, and an amplifying circuit having a function of amplifying a signal.

### Storage Unit

The storage unit 52 has a function of storing measurement information, a programs or data used for a determination as to the degree of soundness as described below (for example, vibration data regarding natural vibration of the structure B), and information such as an obtained determination result regarding the degree of soundness. This storage unit 52 is not particularly limited, and any one of a non-volatile memory and a volatile memory may be used.

### Control Unit

The control unit 53 has a function of controlling, for example, the respective units of the collection device 5 or processing the measurement information. This control unit 53 includes, for example, an MPU.

In particular, the control unit 53 has a function of a “determination unit” that determines the degree of soundness of the structure B using the detection result of the magnetic sensor 2 and the vibration sensor 3. This determination as to the degree of soundness will be described in detail with description of the structure monitoring method which will be described below.

The configuration of the collection device 5 has been described above. The power source that drives the collection device 5 configured in this way is not particularly limited. For example, a commercial power supply or a secondary battery connected to a solar cell may be used.

### Structure Monitoring Method

Hereinafter, a structure monitoring method according to the invention will be described in an example in which the above-described system 1 is used.

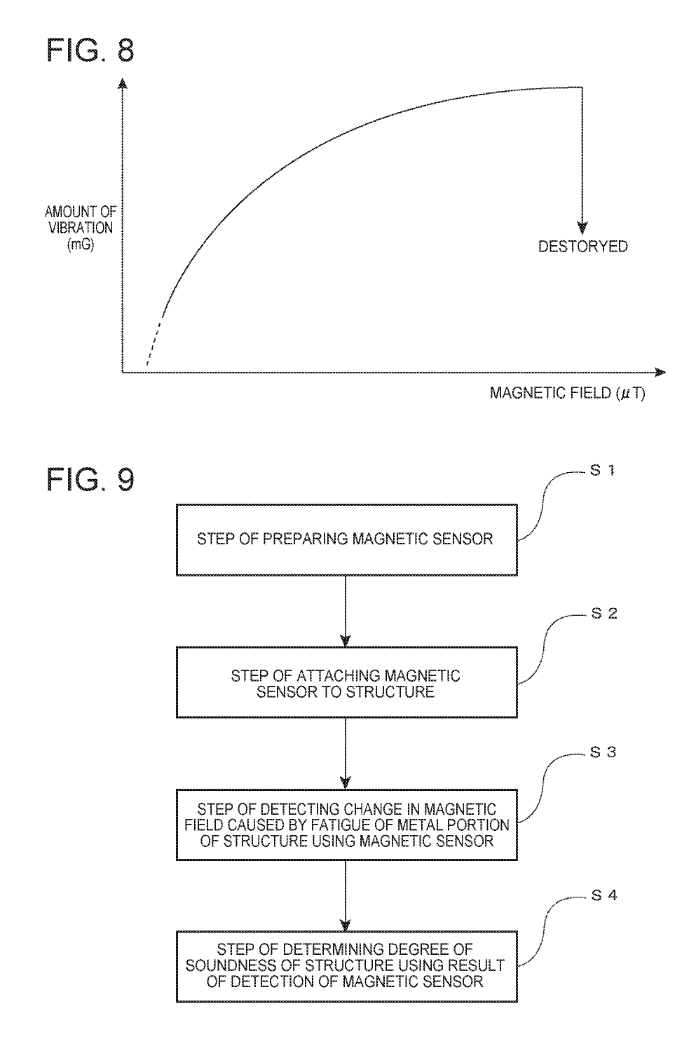

FIG. 7 is a graph illustrating a relationship between a distortion of the metal portion included in the structure and an intensity of a magnetic field generated with the distribution. FIG. 8 is a graph illustrating a relationship between a magnetic field detected by the magnetic sensor and a vibration amount detected by the vibration sensor.

Since the metal portion ST included in the structure B is generally formed of a steel material for a general structure that includes soft iron as a representative example, the metal portion ST exhibits ferromagnetism. In this metal portion ST, a magnetic field generated from the metal portion ST changes with the metal fatigue (distortion), as illustrated in FIG. 7. More specifically, the magnetic field generated from the metal portion ST increases with the progress of the metal fatigue (distortion). Accordingly, it is possible to determine a degree of fatigue of the metal portion ST using the detection result of the magnetic sensor 2.

Further, if the metal fatigue of the metal portion ST progresses, the amount (amplitude) of vibration of the structure B increases when the structure B is vibrated by a constant force. Therefore, from a relationship between the metal fatigue and the amount of vibration, and the result illustrated in FIG. 7 described above, the amount of vibration of the structure B based on the detection result of the vibration sensor 3 increases if the magnetic field from the metal portion ST based on the detection result of the magnetic sensor 2 increases, as illustrated in FIG. 8. It can be determined from this that the amount of vibration of the structure B increases with the metal fatigue of the metal portion ST in a case in which the amount of vibration detected by the vibration sensor 3 increases as the magnetic field detected by the magnetic sensor 2 increases. Further, in a case in which the amount of vibration detected by the vibration sensor 3 suddenly increases with respect to the amount of a change in the magnetic field detected by the magnetic sensor 2, it can be determined that the amount of vibration of the structure B increases due to a factor different from the metal fatigue of the metal portion ST. Further, in a case in which the amount of vibration detected by the vibration sensor 3 reaches a predetermined amount or more and then suddenly decreases, it can be determined that the structure B has been destroyed (a vibration state of the structure B is abnormal). Further, in a case in which the metal portion ST is broken due to the metal fatigue, the magnetic field generated from the metal portion ST rapidly increases. Therefore, when the magnetic field detected by the magnetic sensor 2 rapidly increases in a case in which it is determined that the structure B has been destroyed, it can be determined that the destruction of the structure B is caused by the metal fatigue of the metal portion ST (breaking of the metal portion ST). Further, since a natural frequency of the structure B decreases if deterioration of the structure B progresses, it is also possible to determine a degree of progress of the deterioration of the structure B on the basis of preset vibration data of the structure B and the frequency of the vibration detected by the vibration sensor 3.

It is possible to determine the degree of soundness of the structure B as described above. Hereinafter, a method of using the system 1 described above will be described.

FIG. 9 is a flowchart illustrating a method of using the structure monitoring system illustrated in FIG. 1 (structure monitoring method).

As illustrated in FIG. 9, the method of using a structure monitoring system (structure monitoring method) includes [1] a process of preparing the magnetic sensor 2 (step S1), [2] a process of attaching the magnetic sensors 2 to the structure B (step S2), [3] a process of detecting a change in magnetic field due to metal fatigue of the metal portion ST using the magnetic sensor 2 (step S3), and [4] a process of determining the degree of soundness of the structure B using a detection result of the magnetic sensor 2 (step S4).

In step S1, the magnetic sensor 2 configured as described above is prepared. In this case, the sensor device 4 and the collection device 5 configured as described above are prepared. Only the magnetic sensor 2 may be prepared, and the sensor device 4 may be assembled and the collection device 5 may be prepared after step S2 and before step S3.

In step S2, the magnetic sensor 2 is attached to the structure B, as described above. In this case, the vibration sensor 3 is also attached to the structure B, as described above. Here, the attachment of the sensors may be performed by embedding the sensors prior to curing of the concrete portion C or by perforating the cured concrete portion C and embedding the sensors.

In step S3, the sensor device 4 is operated and magnetic detection is performed by the magnetic sensor 2. Thus, a magnetic field from the metal portion ST can be detected by the magnetic sensor 2. In this case, vibration detection is performed by the vibration sensor 3. Accordingly, the vibration of the structure B can be detected. Here, when the vibration detection is performed by the vibration sensor 3, the vibration detection may be performed by applying vibration to the structure B with a predetermined force from an external device or instrument, and natural vibration of the structure B may be detected by the vibration sensor 3. Detection results of the magnetic sensor 2 and the vibration sensor 3 are transmitted from the sensor unit 4 to the collection device 5 and collected by the collection device 5.

In step S4, in the collection device 5, the degree of soundness of the structure B is determined using the detection results of the magnetic sensor 2 and the vibration sensor 3, as described above.

Thus, it is possible to determine the degree of soundness of the structure B.

According to the system 1 as described above, a fatigue state of the metal portion ST of the structure B can be detected using the magnetic sensor 2 that detects the intensity of the magnetic field from the structure B including the metal portion ST (more specifically, the magnetic field generated with the metal fatigue from the metal portion ST) using the characteristic of an energy transition of the alkali metal atoms. Therefore, it is possible to include information on the fatigue state of the metal portion ST in the result of the determination as to the degree of soundness of the structure B and, as a result, to more accurately monitor the degree of soundness of the structure B including the metal portion ST.

Further, as described above, the control unit 53 of the collection device 5 determines the degree of soundness of the structure B using the detection result of the vibration sensor 3, in addition to the detection result of the magnetic sensor 2. Accordingly, it is possible to include the information on whether or not there is abnormality in vibration of the entire structure B in the result of the determination as to the degree of soundness of the structure B.

Further, the control unit 53 compares the detection result of the vibration sensor 3 with the vibration data stored in the storage unit 52, and determines the degree of soundness using the comparison result. Accordingly, it is possible to determine whether or not there is abnormality in vibration in the entire structure B simply and accurately and include a determination result in the result of the determination as to the degree of soundness of the structure B.

### Second Embodiment

Next, a second embodiment of the invention will be described.

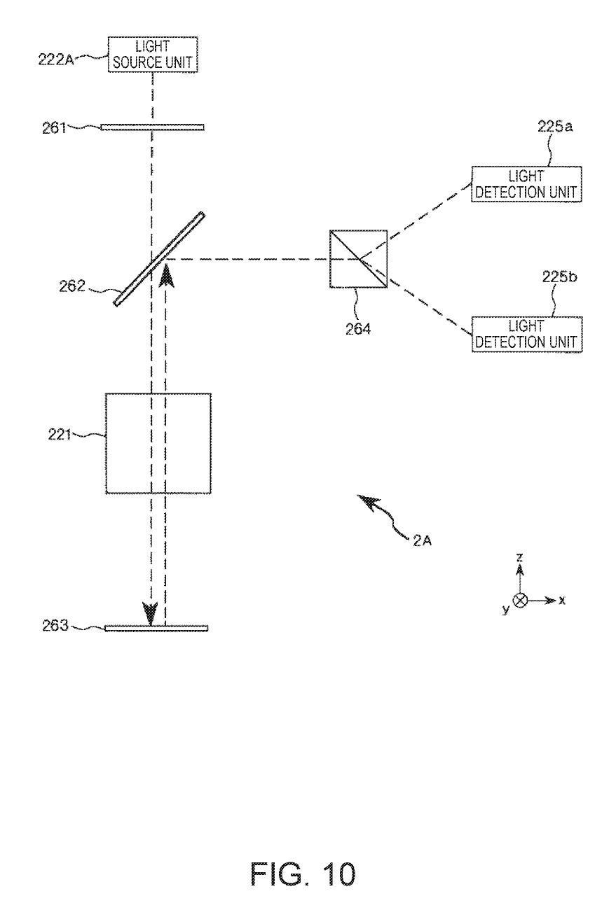

FIG. 10 is a diagram illustrating a schematic configuration of a magnetic sensor used in the structure monitoring system according to a second embodiment of the invention.

Hereinafter, the second embodiment will be described by focusing on a difference between the above-described embodiment and the second embodiment, and description of the same matters will be omitted.

The second embodiment is the same as the first embodiment except that the configuration of the magnetic sensor is different. The same configuration as in the above-described embodiment is denoted with the same reference numeral.

The magnetic sensor 2A used in this embodiment includes a light source unit 222A, a polarization plate 261, a half mirror 262, an atom cell 221, a mirror 263, a polarization separator 264, a light detection unit 225a, and a light detection unit 225b. In FIG. 10, for convenience of description, an x-axis, a y-axis, and a z-axis as three axes orthogonal to each other are illustrated by arrows, a front end side of the arrow is “+”, a base end side “−”, a direction parallel to the x-axis is an “x-axis direction”, a direction parallel to the y-axis is a “y-axis direction”, and a direction parallel to the z-axis is a “z-axis direction”.

The light source unit 222A emits light having a wavelength according to an absorption line of the alkali metal in the atom cell 221. The light source unit 222A is not particularly limited as long as the light source unit can emit the light as described above. For example, a semiconductor laser such as a vertical cavity surface emitting laser (VCSEL) may be used.

The polarization plate 261 is an element that polarizes the light from the light source unit 222A in a specific direction to obtain linearly polarized light.

The half mirror 262 is an element that transmits light directed in the −z axis direction from the light source unit 222A, and reflects the light directed in a +z-axis direction from the atom cell 221, in a direction directed to the polarization separator 264. The half mirror 262 is, for example, a partially polarized beam splitter, or a non-polarizing beam splitter having constant transmittance irrespective of a polarization direction.

The mirror 263 is an element that reflects the light from the light source unit 222A transmitted through the atom cell 221 and inputs the light to the atom cell 221 again. The mirror 263 includes a reflective surface in which a metal film or a dielectric multilayer film is used.

The polarization separator 264 is an element that separates incident light into light of two polarization components that are orthogonal to each other. The polarization separator 264 is, for example, a Wollaston prism or a polarization beam splitter.

The light detection unit 225a and the light detection unit 225b are detectors having sensitivity to a wavelength of the light from the light source unit 222A.

In the magnetic sensor 2A having such a configuration, the light emitted from the light source unit 222A is changed into linearly polarized light having a high degree of polarization by the polarization plate 261. The polarized light is transmitted through the half mirror 262 and is incident on the atom cell 221. The light incident on the atom cell 221 excites the alkali metal atoms filled in the atom cell 221 (optical pumping). In this case, the light is subjected to a polarization plane rotation action according to the intensity of the magnetic field, and the polarization plane is rotated. The light transmitted through the atom cell 221 is reflected by the mirror 263 and incident on the atom cell 221 again. The light incident on the atom cell 221 is subjected to the polarization plane rotation action again. The light transmitted through the atom cell 221 is reflected by the half mirror 262 and split into light of two polarization components by the polarization separator 264. Intensities of the light of the two polarization components are respectively detected by the light detection unit 225a and the light detection unit 225b.

Here, an interaction of atoms and light for magnetic field measurement (polarization plane rotation action) is basically divided into three steps including a pump process, a precession process, and a probe process. Hereinafter, an operation of the element in each step will be described.

For example, in a case in which the cesium is filled in the atom cell 221, and the light from the light source unit 222A is linearly polarized light having a wavelength that excites the ultrastructure quantum number of the cesium from a base state of F=3 to an excitation state of F′=4 and having an electric field (electric field vector Ei) vibrating in the y-axis direction, outermost electrons of the cesium are excited (optical pumping) and the angular momentum of the cesium atoms (more accurately, spin angular momentum) is distributed to be biased along the electric field of the incident light. In this case, since the electric field of the incident light is vibrating in the y-axis direction, the angular momentum is mainly distributed to be biased toward the +y direction and the −y direction. That is, the optically pumped cesium atom has two angular momentums that are antiparallel called a +y-axis direction and a −y-axis direction. Here, an anisotropy occurring in the distribution of the angular momentum is referred broadly to as “alignment”, and causing an anisotropic distribution in the angular momentum is referred to as “forming the alignment.” In other words, the formation of the alignment refers to magnetization.

If a static magnetic field is applied in the z-axis direction in a state in which the alignment is formed by optical pumping as described above, the cesium atoms receive a clockwise rotational force using an axis line parallel to the z-axis (an axis line parallel to the static magnetic field) as a rotation axis due to an action of the static magnetic field and the alignment. This rotation force rotates the cesium atoms in an xy plane. This is a precession. The rotation of the cesium atoms refers to rotation of the alignment. Here, a rotation angle of the alignment relative to the alignment in a state in which the magnetic field is not applied is assumed to be α. In terms of a single atom, biasing (excitation state) of an angular momentum caused by pumping decreases over time. That is, the alignment relaxes. Since the laser beam is CW light, formation and relaxation of the alignment are simultaneously repeated in parallel and continuously. As a result, steady (time-average) alignment is formed in terms of a whole population of atoms. The magnitudes of the rotation angle α and the angular momentum of the alignment depend on a precession frequency (Larmor frequency) and a relaxation rate determined by several factors.

By such a steady alignment, the light from the light source unit 222A is subjected to a linear dichroism action in the atom cell 221. A direction of the alignment is the transmission axis, and a polarization component in this direction is mainly transmitted. A direction perpendicular to the alignment direction is the absorption axis, and a polarization component in this direction is mainly absorbed. That is, if amplitude transmission coefficients of the light in the transmission axis and the absorption axis are represented as t// and t⊥, t//>t⊥. A transmission axis component and an absorption axis component of an electric field Ei of the incident light are Ei cos α and Ei sin α. The transmission axis component and the absorption axis component of the electric field Eo after the electric field Eo is transmitted through the atom cell 221 (after the electric field Eo interacts with the cesium atoms) are t//Ei cos α and t⊥Ei sin α. Since t//>t⊥, the electric field vector Eo rotates relative to the electric field vector Ei (that is, the polarization plane of the laser beam rotates). This rotation angle is φ.

More accurately, a phenomenon that an angular momentum is biased in a propagation direction of the laser beam (alignment orientation conversion: AOC) occurs and, as a result, rotation of the polarization plane due to circular birefringence (Faraday effect) occurs. However, this phenomenon is ignored in the description.

The light of which the polarization plane is rotated by the steady alignment as described above is split into two polarization components by the polarization separator 264. For example, the two polarization components are split into components along the two axes of a first detection axis and a second detection axis. The first detection axis is inclined +45° relative to the polarization plane in a case in which there is no rotation of the polarization plane (φ=0). The second detection axis is inclined −45° relative to the polarization plane in the case in which there is no rotation of the polarization plane. The light detection unit 225a and the light detection unit 225b detect the light amount of components along the first detection axis and the second detection axis, respectively. A first detection axis component of an electric field vector Eo of the light transmitted through the atom cell 221 is Eo cos(π/4−φ), and a second detection axis component is Eo sin(π/4−φ). Here, in a case in which the rotation of the polarization plane is substantially zero (φ≡0), the intensity (light amount) of the light incident on the light detection unit 225a and the light detection unit 225b is substantially the same. Conversely, in a case in which there is a difference in the amount of the light incident on the light detection unit 225a and the light detection unit 225b, the polarization plane is shown to be rotated. This means that there is a magnetic field. The difference between the amounts of light incident on the light detection unit 225a and the light detection unit 225b is a function of the rotation angle φ of the polarization plane. By obtaining a difference between the output signals of the light detection unit 225a and the light detection unit 225b, information on the rotation angle φ can be obtained. The rotation angle φ is a function of an applied static magnetic field. Accordingly, the information on the applied static magnetic field is obtained by the rotational angle φ.

The magnetic sensor 2A as described above detects the intensity of the magnetic field using a non-linear magneto-optical effect of the alkali metal atoms. Accordingly, it is possible to detect the magnetic field from the metal portion ST with high accuracy using the magnetic sensor 2A.

Although the structure monitoring system and the structure monitoring method according to aspects of the invention have been described on the basis of the illustrated embodiments, the invention is not limited thereto.

For example, in the invention, the configuration of each unit may be replaced with any configuration having the same function, and any configuration may also be added.

Further, although the case in which the detection results from the plurality of sensors are collectively transmitted by one communication unit has been described by way of example in the above-described embodiments, the communication unit may be provided in each sensor. In this case, each communication unit may transmit information to the collection device 5 or at least one communication unit may function as a parent device, collect information from the other communication units, and then, collectively transmit the information to the collection device 5.

Further, although the case in which the detection result of each sensor is wirelessly transmitted to the collection device has been described by way of example in the above-described embodiments, the detection result of each sensor may be transmitted to the collection device in a wired manner.

What is claimed is:

1. A structure monitoring system, comprising:
a magnetic sensor that detects an intensity of a magnetic field from a structure including a metal portion using characteristics of an energy transition of alkali metal atoms; and
a determination unit that determines a degree of soundness of the structure using a result of the detection of the magnetic sensor.

2. The structure monitoring system according to claim 1, further comprising:
a vibration sensor that detects vibration of the structure,
wherein the determination unit determines the degree of soundness using a result of the detection of the vibration sensor, in addition to the result of the detection of the magnetic sensor.

3. The structure monitoring system according to claim 2, further comprising:
a storage unit that stores vibration data regarding natural vibration of the structure,
wherein the determination unit compares the detection result of the vibration sensor with the vibration data and determines the degree of soundness using a result of the comparison.

4. The structure monitoring system according to claim 1,
wherein the determination unit determines a degree of fatigue of the metal portion using the detection result of the magnetic sensor.

5. The structure monitoring system according to claim 1,
wherein the magnetic sensor includes:
an atom cell filled with alkali metal;
a light source unit that irradiates the atom cell with light; and
a light detection unit that detects the light transmitted through the atom cell,
wherein a body portion including the atom cell, the light source unit, and the light reception unit and formed as a unit is attached to the structure.

6. The structure monitoring system according to claim 5,
wherein the magnetic sensor includes a circuit unit which is electrically connected to the light source unit and the light detection unit, and
the circuit unit is separated from the body portion.

7. The structure monitoring system according to claim 5,
wherein when the atom cell and the metal portion are viewed from an alignment direction, the atom cell is included in the metal portion.

8. The structure monitoring system according to claim 1, further comprising:
a communication unit that wirelessly transmits the detection result of the magnetic sensor.

9. The structure monitoring system according to claim 8,
wherein the communication unit is driven by power from a battery.

10. The structure monitoring system according to claim 1,
wherein the magnetic sensor detects an intensity of a magnetic field using a non-linear magneto-optical effect of the alkali metal atoms.

11. The structure monitoring system according to claim 1,
wherein the magnetic sensor detects an intensity of a magnetic field using an electromagnetically induced transparency phenomenon of the alkali metal atoms.

12. A structure monitoring method, comprising:
preparing a magnetic sensor that detects an intensity of a magnetic field using characteristics of an energy transition of alkali metal atoms;
attaching the magnetic sensor to a structure including a metal portion;
detecting a change in magnetic field caused by fatigue of the metal portion using the magnetic sensor; and
determining a degree of soundness of the structure using a result of the detection of the magnetic sensor.
